(19) United States
(12) Patent Application Publication
(10) Pub. No.: US 2013/0061909 A1
(43) Pub. Date: Mar. 14, 2013

(54) DEVICE SHAPED SO THAT IT CAN BE USED ALONE TO SECURE A SOLAR PANEL TO A SINGLE BEAM OF A SUPPORT STRUCTURE, AND UNIT COMPRISING ONE SUCH DEVICE

(71) Applicant: Claude Jacquot, Saint Eustache (FR)

(72) Inventor: Claude Jacquot, Saint Eustache (FR)

(21) Appl. No.: 13/501,625

(22) PCT Filed: Oct. 13, 2010
(86) PCT No.: PCT/FR2010/052174

§ 371 Date: Aug. 6, 2012

(30) Foreign Application Priority Data
Oct. 13, 2009 (FR) 0957178

(51) Int. Cl. H01L 31/052; F16M 13/02; F24J 2/38

(52) U.S. Cl. 136/246; 126/600; 248/126

(57) ABSTRACT

The invention relates to a device which is shaped so that it can be used alone to secure a solar panel (1) to a single beam (4) of a support structure and which comprises: an interface (2) including first securing means (3a-3d) for securing the solar panel (1) to the interface (2) and second securing means (6) for securing the interface (2) to the beam (4). The first securing means (3a-3d) are shaped to retain the solar panel (1) by affixing the passive face thereof to a surface of the interface (2) or using hooks (3a-3d) which cover part of the edge of an active face of the solar panel (1). The interface (2) includes an intermediate structure (7) which mechanically and solidly connects the first securing means (3a-3d) and the second securing means (6) and which insulates the panel (1) in relation to mechanical stresses from the beam (4).

The present invention relates to solar panel support structures, and more particularly the means making it possible to secure a solar panel to a support structure having beams.

There are two types of solar panels:
thermal solar panels, called thermal solar sensors or simply solar sensors, which convert solar light into heat recovered and used in the form of hot water, and
photovoltaic solar panels, called photovoltaic modules or simply solar panels, which converts solar light into electricity.

The present invention is adapted for both types of solar panels mentioned above, as well as for solar panels combining the two types of sensors, i.e. photovoltaic sensors and thermal sensors.

A simple and inexpensive support structure is known, made up of beams making up girders and crossbeams, on which the solar panels are secured as follows: the longitudinal edges of the solar panels are secured on two successive parallel beams. The securing of the solar panels on the beams is usually done using screwing means. The use of screwing means is limited to specific and expensive screwing means, due to the great fragility of the solar panels.

Furthermore, securing solar panels by screwing is a lengthy operation. In particular, in the case of “solar farm” facilities, provided to supply a large quantity of electricity, which may be up to 50 MW, the installation times are scaled up, since such solar farms in practice comprise approximately 600,000 panels each secured to a support structure.

For optimal operation, and to avoid the mechanical stresses of a nature to deteriorate it, the solar panel must be contained in a single plane. However, it is very difficult to mount the support structure so that the beams are all contained in a single plane, such that the solar panels, once mounted, are also all contained in the single plane without undergoing mechanical stresses.

Operators lose considerable time adapting the support structure in order to ensure that flatness, in particular in the case of solar farms.

Known from DE-A-10 2006 036 150 is a structure for securing a solar panel to a beam supported by a mast, using several girders connected by crossbeams. The girders and crossbeams form an area receiving a rear surface of the solar panel, turned opposite the rays of the sun. However, it is difficult to obtain flatness in this area and flatness defects may deteriorate the solar panel. In particular, when the girders and the crossbeams are subject to mechanical stresses, in particular resulting from manipulation of the structure or temperature changes, they transmit those mechanical stresses to the solar panel, which is not satisfactory, since the solar panel then risks becoming damaged.

Also known, in the field of solar panel support structures, is document EP 2 071 102 A2, which describes a support structure of the vertical mast type, comprising:
first rivet fastening means to secure a photovoltaic panel to an interface,
second screw fastening means to anchor the mast structure in the foundations provided in the ground.

The vertical mast includes an anchoring end provided to be anchored directly by screwing in the foundations provided in the ground, and riveting means for securing one or two photovoltaic panels at a stationary predefined orientation. These fastening means are mechanically secured to the vertical anchoring mast, the different metal parts being assembled by welding.

Due to its anchoring in foundations, such a structure requires prior preparation work to produce foundations on the final usage site. This prior work is expensive, in particular in the case of solar farms.

Furthermore, this type of support structure cannot be secured to a support structure having beams.

Such a support structure is a suitable solution for producing an average quantity of energy, but it is absolutely not suitable for supplying a large quantity of electricity, in a solar farm.

This support structure with vertical masts assembled by welding is absolutely not provided to make up a support that can be multiplied in large numbers and cost-effectively to support a large number of solar panels.

The problem proposed by the present invention is to design a device so that it can be used alone to secure a solar panel to a single beam of a support structure, which may be preassembled and that is quick to assemble on the support structure so as to reduce costs and that does not risk damaging the solar panel. In particular, one aim is to eliminate the difficulties encountered to date to ensure the flatness of the support structure having the beams.

To achieve these aims and others, the invention proposes a device which is shaped to secure by itself a solar panel to a single beam of a support structure, comprising an interface including first fastening means for securing the solar panel to the interface and second fastening means for securing the interface to the beam. The first fastening means are shaped to retain the solar panel by affixing the passive face thereof to a surface of the interface or using hooks which cover part of the edge of an active face of the solar panel. The interface includes an intermediate structure which mechanically secures the first fastening means and the second fastening means and which fulfills a mechanical dissociation function of the panel with regard to the beam.

The idea at the base of the invention is therefore to design a device for mechanically separating each solar panel relative to the support structure, i.e. to design a device that does not transmit the deformations from the single beam of the support structure to which the panel is secured to said solar panel. The invention also allows quick and easy securing of the solar panel to a single beam of the support structure, in particular with the aim of assembling solar farms quickly and easily.

A device according to the invention may be pre-mounted with the solar panel.

The solar panel-interface assembly is quick to assemble and mount on the support structure on the final usage site, without requiring prior adjustment of the flatness of the support structure, which is particularly advantageous in the case of solar farms.

In the case where the solar panel and the interface are pre-mounted on the support structure, the mechanical stresses that necessarily appear in the support structure during the movement and placement thereof are not transmitted to the solar panel.

This design makes it possible to secure the interface to a single beam. In this way, the number of beams to be provided in the support structure is reduced, and the beams to be provided can also be shorter. This results in cost savings in the manufacture and mounting of the support structure.

Flatness defects in the support structure are a well-known problem of solar panels, and may constitute a major drawback in the use thereof. The present invention offers an effective solution to this problem. In fact, the flatness of the solar panels and the absence of mechanical stresses are ensured by the interface itself, and not by the support structure, as is usually the case.

The invention also makes it possible to use, without drawbacks for the solar panels, less rigid, and therefore lighter and less expensive, support structures.

It is advantageously possible to provide that the first fastening means are adhesive means or elastic snapping means.

These first fastening means are quick to use, effective and inexpensive, and they facilitate pre-mounting.

Advantageously, it is possible to provide that the first fastening means are shaped to retain the solar panel in four peripheral areas.

In this way, the solar panel is suitably secured to the support structure in the face of bad weather.

Advantageously, it is possible to provide that the second fastening means are adhesive means, elastic snapping means, sliding engagement means, or any other means not requiring tools and allowing locking.

The second fastening means are quick to implement, effective and inexpensive. They reduce mounting time. The sliding engagement makes it possible to reduce costs.

It is advantageously possible to provide that the device includes a plastic body.

The body of the interface is then lighter than an interface made from metal and provides electrical insulation between the panel and the metal rail. This body may make up the intermediate structure in whole or in part.

Advantageously, it is possible to provide that the intermediate structure includes integrated orientation means to orient the solar panel along at least one orientation axis.

In this way, the solar panel can be oriented to track the maximum light direction. The daily quantity of solar light received by the solar panel is increased.

Advantageously, it is possible to provide that the orientation means make it possible to orient the solar panel along two orientation axes, i.e. an azimuth axis and a declination axis.

In this way, the solar panel can be oriented to more faithfully track the movements of the sun so as to maximize the daily quantity of solar light received by the solar panel year-round.

It is advantageously possible to provide that the interface includes an actuator driven by a control member and capable of actuating the orientation means along the orientation axis or axes.

The orientation of the solar panels can thus be programmed or enslaved.

Advantageously, it is possible to provide that the interface includes integrated electrical connection means, capable of transmitting the electricity generated by the solar panel to the support structure and/or capable of transmitting measurement signals and/or control signals.

In this way, it is possible to facilitate the connection to an electrical network provided directly in the support structure, to directly convey the electricity generated by the solar panel.

Advantageously, it is possible to provide that the interface includes passages for a coolant between the solar panel and the support structure.

In this way, the coolant can cool the solar panel to improve the output of the solar panel.

Advantageously, it is possible to provide that holes or notches are formed in the solar panel and cooperate with the hooks.

The invention also relates to an electricity production unit, in particular of the “solar farm” type, including solar panels each secured to a single beam of a support structure using a device as mentioned above.

Other aims, features and advantages of the present invention will emerge from the following description of specific embodiments, done in reference to the attached figures, in which:

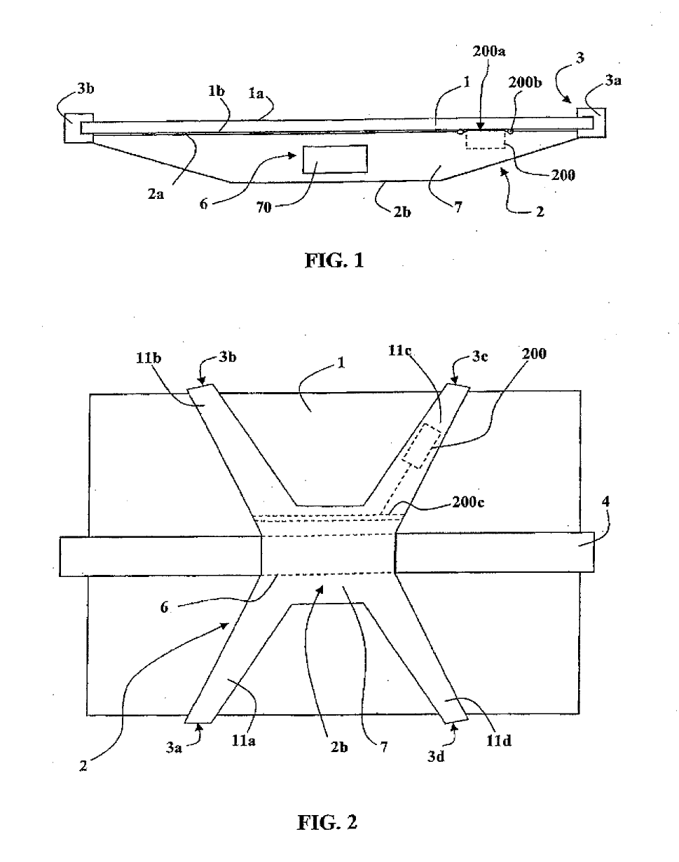

FIG. 1 is a side view of a solar panel-interface assembly according to a first embodiment of the invention;

FIG. 2 is a bottom view of the solar panel-interface assembly of FIG. 1 secured to a beam of the support structure;

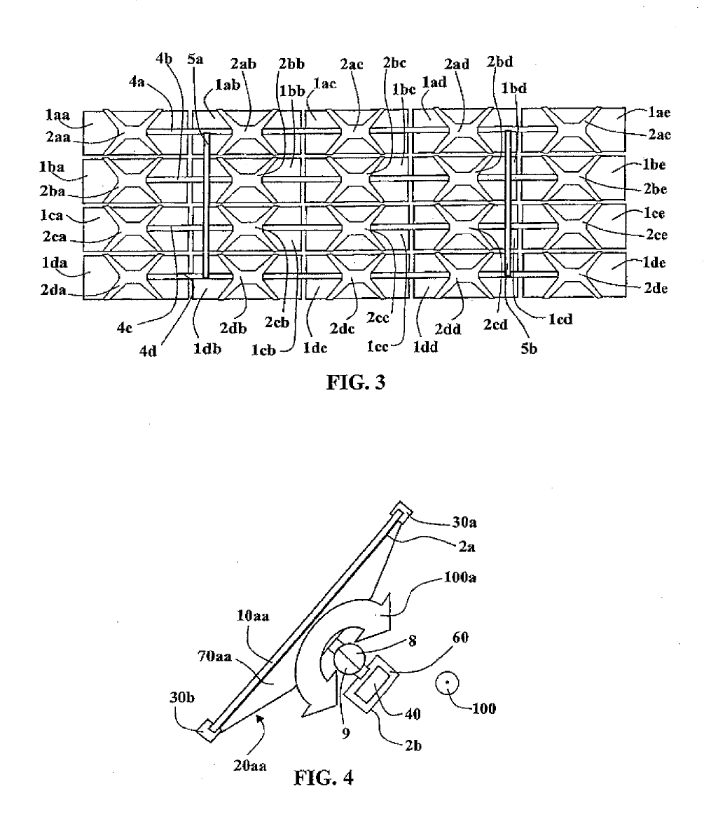

FIG. 3 is a bottom overview diagram of a solar panel-interface assembly of the type shown in FIGS. 1 and 2;

FIG. 4 is a side view of a solar panel-interface assembly according to a second embodiment;

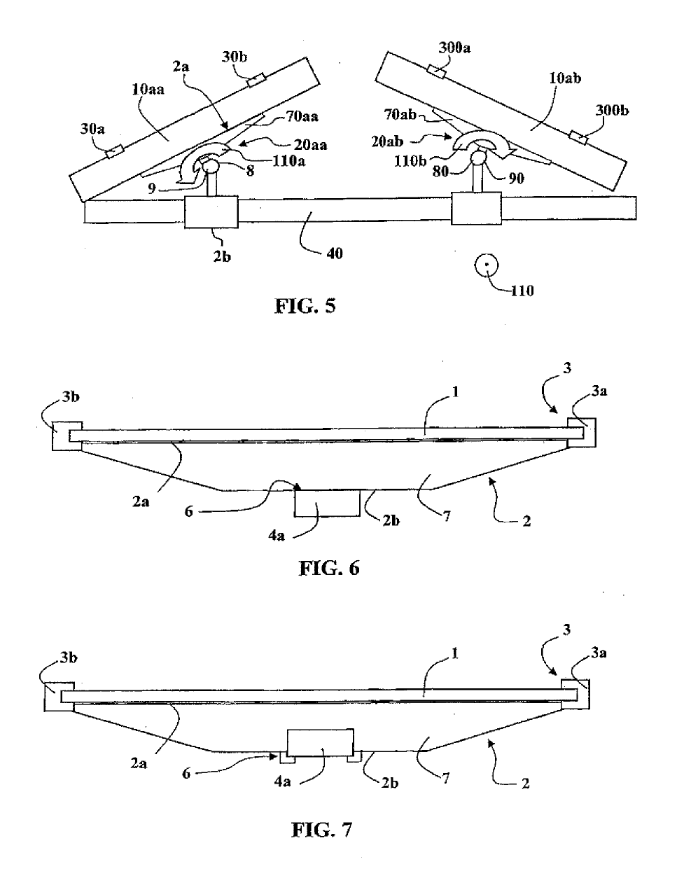

FIG. 5 is a longitudinal view of the solar panel-interface assembly of FIG. 4;

FIG. 6 is a side view of a solar panel-interface assembly according to a third embodiment;

FIG. 7 is a side view of a solar panel-interface assembly according to a fourth embodiment;

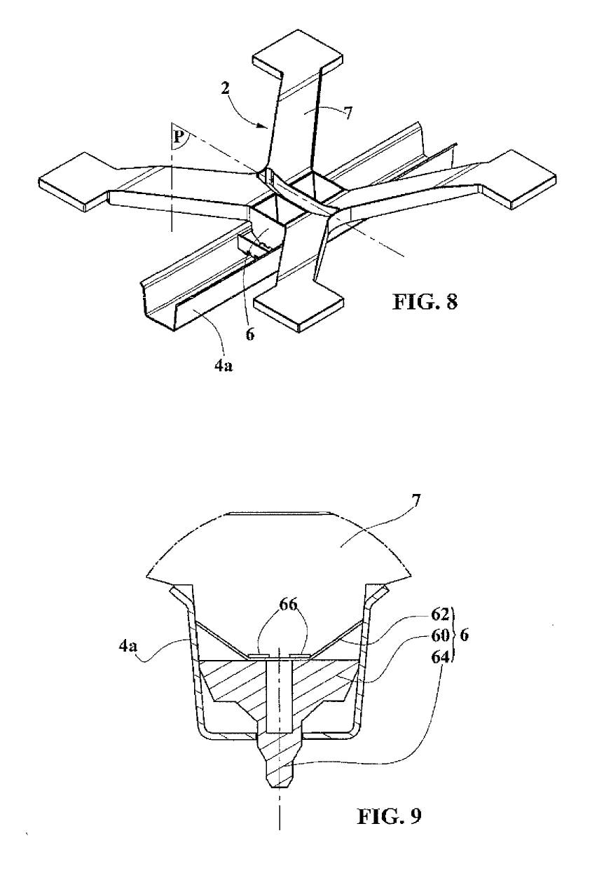

FIG. 8 is a perspective view of an interface according to a fifth embodiment, secured to a beam of a support structure; and

FIG. 9 is a cross-sectional view along plane P of FIG. 8.

In all of the embodiments described hereinafter, we essentially describe the interface making up the device securing by itself a solar panel to a single beam of a support structure having girders, as the interface is the heart of the present invention. In the description below, the beams are girders, but they could also be crossbeams.

FIG. 1 illustrates a solar panel-interface assembly with a solar panel 1 secured to an interface 2. The interface 2 is shaped to secure a solar panel 1 to a support structure having girders 4 (FIG. 2).

The solar panel 1 includes an active face 1a that receives the light from the sun, and a passive face 1b opposite the active face 1a.

In the embodiments shown in FIGS. 1 and 2, the interface 2 includes:
first fastening means 3 for securing the solar panel 1 to the interface 2,
second fastening means 6 for securing the interface 2 to the support structure 4, and
an intermediate structure 7 for mechanically securing the first fastening means 3 and the second fastening means 6.

The first fastening means 3 include elastic snapping means 3a to 3d. In FIG. 1, only the elastic snapping means 3a and 3b are shown. In FIG. 2, the elastic snapping means 3a to 3d are all shown.

The elastic snapping means 3a to 3d are a sort of hook with elastic radial displacement that covers part of the edge of the active surface 1a of the solar panel 1 to retain it and maintain it bearing by its passive face 1b against the interface 2. In this way, the securing of the solar panel 1 to the interface 2 is done by hooking using elastic hooks. Alternatively, the hooks may not be elastic. Complementarily, advantageously but not necessarily, holes or notches, not shown, are formed in the solar panel 1 and cooperate with the elastic snapping means 3a to 3d, so as to facilitate the securing of the solar panel 1 on the interface 2.

The intermediate structure 7 has a substantially trapezoidal transverse section in side view, with two parallel end surfaces, i.e. a small end surface 2b and a large end surface 2a.

The large end surface 2a is shaped to be flat so as to receive the passive face 1b of the solar panel 1. The dimensions thereof correspond to those of the passive face 1b of the solar panel 1. The flatness of the large surface 2a is essential to meet the flatness requirement and have no mechanical torsion stresses on the solar panels.

The small end surface 2b occupies a more reduced surface, corresponding to the dimensions of the second fastening means 6.

In this embodiment, the intermediate structure 7 includes, at the small end surface 2b, a through housing 70 to receive a single girder 4 (FIG. 2) of the support structure. This housing 70 produces the second fastening means 6, which are shaped to be secured to a single girder. In this way, the interface 2 is secured to a single girder 4 (FIG. 2) of the support structure.

In this embodiment, the mechanical securing is done by sliding engagement and locking means.

The mounting of the intermediate structure on the girder 4 is quick and easy: one need only slide the girder 4 into the housing 70. This is particularly advantageous in the case of installation of a solar farm, as mounting times are multiplied.

FIG. 2 is a bottom view of the solar panel-interface assembly of FIG. 1, once secured to a girder 4. The interface 2 is inserted between the solar panel 1 and the girder 4 of the support structure. One can see the solar panel 1, the interface 2 including the intermediate structure 7 in which a housing 70 is provided (FIG. 1) to slidingly receive the girder 4 of the support structure. The interface 2 also includes the first fastening means 3.

In this FIG. 2, the four elastic snapping means 3a to 3d are shown, and are spaced apart from one another by a distance such that the elastic snapping means 3a to 3d engage in four peripheral areas of the solar panel 1. The elastic snapping means 3a to 3d are connected to the small end surface area 2b by the intermediate structure 7 having bars 11a to 11d, respectively. The bars 11a to 11d extend substantially in a hub and spoke structure from the small end surface area 2b. They are shaped to retain the solar panel 1 in four peripheral areas.

These peripheral areas are defined with the manufacturers of the solar panels and can be adapted easily as a function of the type of solar panel to be mounted. They may be called upon to evolve, without going beyond the scope of the present invention.

The four elastic snapping means 3a to 3d are provided to effectively retain the solar panel 1 to face bad weather and prevent deterioration. They are shaped to respect the flatness of the solar panel 1. It is easier to manufacture an interface respecting the flatness of the solar panel independently of the flatness of the girders of the support structure than to modify non-flat girders of a support structure to make them flat.

In one embodiment not illustrated, the solar panel is affixed to the large end surface 2a of the intermediate structure 7. The elastic snapping means 3a to 3d are therefore not present in this embodiment.

The intermediate structure 7 constitutes a mechanical stress filtering structure, inasmuch as the intermediate structure 7 does not transmit, to the panel 1, the deformations of the girder 4 caused, for example, by temperature variations or handling and transport of the support structure. In other words, the intermediate structure 7 fulfills a mechanical dissociation function of the solar panel 1 with regard to the girder 4.

FIG. 3 illustrates a bottom view of an assembly of four rows and five columns of solar panel-interface assemblies of the type shown in FIGS. 1 and 2, associated with the same support structure. The corresponding support structure includes four girders 4a to 4d and two crossbeams 5a and 5b.

FIG. 3 diagrammatically illustrates a sub-assembly of a solar farm, or a roof with structures for receiving panels, with the understanding that in practice, the solar farm may comprise a large number of such sub-assemblies, for example in the vicinity of 12,000.

The solar panels of the first row are referenced using numerical reference 1a, then a, b, c, d and e to describe the columns. The corresponding interfaces are referenced by numerical reference 2a, then a, b, c, d and e to describe the columns.

The solar panels of the second row are referenced using numerical reference 1b, then a, b, c, d and e to describe the columns. The corresponding interfaces are referenced by numerical reference 2b, then a, b, c, d and e to describe the columns.

The solar panels of the third row are referenced using numerical reference 1c, then a, b, c, d and e to describe the columns. The corresponding interfaces are referenced by numerical reference 2c, then a, b, c, d and e to describe the columns.

The solar panels of the fourth row are referenced using numerical reference 1d, then a, b, c, d and e to describe the columns. The corresponding interfaces are referenced by numerical reference 2d, then a, b, c, d and e to describe the columns.

Each intermediate structure of each interface includes a housing 70 (FIG. 1) for slidingly receiving a girder as illustrated in FIG. 2. In this way, the interfaces of the first row are connected to one another by the girder 4a, those of the second row by the girder 4b, those of the third row by the girder 4c, and those of the fourth row by the girder 4d. The girders 4a to 4d are connected to one another by two crossbeams 5a and 5b.

Owing to the securing of each solar panel using an individual connection to a single girder, there need only be as many girders as there are rows of solar panels, and each girder is shorter than the total length of all of the solar panels, as shown in FIG. 3. Furthermore, any flatness or parallelism defect between the girders does not produce a mechanical stress on the solar panels.

FIGS. 4 and 5 illustrate a second embodiment of the invention in which two solar panels 10aa and 10ab can be oriented along two orientation axes 100 and 110. The orientation axis 100 is parallel to the girder 40. This may be a declination axis. The orientation axis 110 is perpendicular to the girder 40. This may be an azimuth axis.

FIG. 4 is a side view of this embodiment. Thus, only solar panel 10aa is shown. The orientation movement is illustrated by arrow 100a. FIG. 5 is a longitudinal view of this second embodiment. The two solar panels 10aa and 10ab are shown spaced away from one another along the arrows 110a and 110b.

The solar panel 10aa is secured to an interface 20aa to obtain a solar panel-interface assembly that can be secured on a girder 40. The solar panel 10ab is secured to an interface 20ab to obtain a solar panel-interface assembly that can be secured on a girder 40.

In this second embodiment, each interface 20aa and 20ab includes:
first fastening means 30a, 30b and 300a and 300b, of the same type as those of the first embodiment, i.e. elastic snapping means,
second fastening means 60, for example a housing for slidingly receiving the girder 40, and
an intermediate structure 70aa and 70ab, with a substantially trapezoidal profile, as in the first embodiment.

The interface 20aa or 20ab differs from the first embodiment in that it includes an actuator 9 or 90 capable of actuating the orientation means 8 or 80. The orientation means 8 or 80 make it possible to orient the solar panel 10aa or 10ab along the orientation axis 100 and/or along the orientation axis 110.

The actuator 9 is controlled by a microcontroller control unit (not shown), programmed so that the solar panels 10aa and 10ab track the maximum light direction in order to maximize electricity production. The solar panel itself may be used as a light sensor, by using its output voltage as light measurement signal.

In this embodiment of FIGS. 4 and 5, each solar panel is oriented independently of the others by steering its actuator 9 or 90. The actuating energy may be taken from the solar panel itself, and the interface 20aa or 20ab may include the control unit ensuring said steering.

In this way, the orientation control of the panels is optimized, in particular by the fact that the inertia of the elements to be moved for that orientation is substantially reduced. Furthermore, in this way, the orientation axes of the solar panel 1 are close to the solar panel 1, which decreases the energy that the actuator must supply to move the solar panel 1. In this way, the overall output of the assembly is optimized.

Furthermore, since the solar panel-interface assembly is autonomous, it is not necessary to use wired connections to connect the assembly to a control center since, advantageously, the solar panel 1 can serve both as electricity generator, making it possible to power the actuator 9, and light sensor, to enslave the actuator 9 as described above.

Each panel is independent and autonomous, which facilitates breakdown and installation management. The number of panels becomes irrelevant.

These interface means with individual orientation means integrated into the solar panels constitute an independent invention in themselves, which may be used independently of the nature of the second fastening means to the support structure. In other words, such interfaces may be used for securing to different support structures, for example individual support structures for securing on a building.

FIG. 6 illustrates a third embodiment of the invention. The same essential means are referenced here using the same numerical references as in FIG. 1. Here, the interface 2 is secured to a girder 4a by affixing the small end surface 2b of the intermediate structure 7 on the girder 4a.

FIG. 7 illustrates a fourth embodiment of the invention. The same essential means are referenced here using the same numerical references as in FIG. 1. Here, the interface 2 is secured to a girder 4a by elastic snapping of a girder 4a to the intermediate structure 7.

FIGS. 8 and 9 illustrate a fifth embodiment of the invention. The same essential means are referenced here using the same numerical references as in FIG. 1. In FIGS. 7 and 8, the solar panel 1 is not shown and can be secured to the interface 2 similarly to the fasteners described for the preceding embodiments. Here, the interface 2 is secured to a girder 4a by a buttressing system.

As shown in FIG. 8, the transverse section of the girder 4a is U-shaped. The second fastening means 6 comprise a body 60, connected to the intermediate structure 7, a centering pin 64 and at least one elastic element 62 that includes two flexible lateral wings and whereof the resting width is slightly larger than the distance between the side walls of the U-shaped profile of the girder 4a. The centering pin 64 is oriented opposite the intermediate structure 7, while each elastic element 62 is secured to a surface of the body 60 facing the intermediate structure 7, for example using rivets 66. A hole is formed in the bottom of the U-shaped profile of the girder 60. During securing of the interface 2 on the girder 4a, the user inserts the interface 2 into the girder 4a and pushes the centering pin 64 into the opening of the girder 4a. This results in folding the side wings of the elastic element 62 down, which then rub against the side walls of the girder 4a. The tapered section of the centering pin 64 facilitates this operation. This advantageously makes it possible to position the interface 2 relative to the girder 4a easily, without needing to perform prior measurements. Once the interface 2 is pushed into the bottom of the girder 4a, it is no longer possible to remove it, since each elastic element 62 presses against the side walls of the girder 4a. In this way, it is not possible to remove the interface 2 from the girder 4a without damaging it, which makes it possible to protect against theft.

In each case, the interface 2 is adapted as a function of the shape of the support structure, to allow assembly without tools.

We will now describe one possible method for mounting, on the support structure, solar panel-interface assemblies that are assembled beforehand.

The solar panel-interface assemblies are transported in their assembled state to a final usage site. On the final usage site, the support structure is mounted, i.e. the girders and the crossbeams are assembled to form the support structure.

The girders making up the upper portion of the support structure are secured to the interfaces, either by adhesion or by elastic snapping, or by sliding, with locking.

It is also possible to provide for transporting the solar panel-interface assemblies already assembled to the support structure, since the deformations of the plane thereof are not transmitted to the panels.

As previously indicated, the device according to the invention can advantageously include, in the interface 2, electric and conduction connecting means for the electrical current and electrical measuring or control signals, between the solar sensor 1 and the support structure.

In this respect, FIGS. 1 and 2 diagrammatically illustrate an electric connection compartment 200, provided in the interface 2, and comprising an opening 200a emerging on the large end surface 2a of the interface 2. Sealing means 200b, such as a peripheral seal, are provided on the periphery of the opening 200a, and are shaped to ensure sealing of the compartment 200 when the interface 2 is pressed by the fastening means 3a and 3b against the passive face 1b of the solar panel 1.

In the compartment 200, it is possible to provide a junction box containing connectors capable of connecting automatically to conductors provided on the passive face 1b of the solar panel 1, the connection being done by simply bringing the solar panel 1 and the interface 2 close together. Alternatively, the connectors may be welded to the conductors, in the case where the interface 2 is secured to the solar panel 1 not on the site, but during manufacture. The connectors of the compartment 200 are connected, by internal conductive lines provided in the interface 2, to interface output connectors that may then be connected to conductors provided in or on the support structure. In this way, when the solar panel 1 has been assembled to the interface 2, the only electrical connections that remain to be made are the electrical connections between the interface 2 and the support structure. In this way, the interface 2 may be equipped with connectors compatible with those of the support structure, which is not possible with the connection means generally provided on bare solar panels 1.

According to one possibility, the interface 2 may comprise cable passages such as the longitudinal passage 200c (FIG. 2), capable of receiving and supporting cable lines connecting the successive interfaces and electrically connected to the connectors of the compartments 200.

Alternatively, the interface 2 may comprise, in the small end surface area 2b thereof, electrical connectors connected by lines integrated into the connectors of the compartment 200 and capable of connecting automatically to conductors provided on the girder 4 of the support structure during the assembly movement of the interface 2 on the support structure.

This arrangement of an interface 2 provided with electrical connection means can be used independently of the particular fastening means for securing the interface 2 to the support structure. In other words, this is an independent invention from the other particular means of the interface 2, in particular means for securing to the support structure. In other words, it is possible to consider using such interfaces for securing to different support structures, for example individual support structures for securing on a building.

Irrespective of the embodiment, the intermediate structure 7 or 70 performs the mechanical separation or stress filtering function between the solar panel 1 or equivalent means and the girder 4 or equivalent means.

The present invention is not limited to the embodiments explicitly described, but on the contrary encompasses various alternatives and generalizations contained in the field of the claims below.

1-12. (canceled)

13. A device which is shaped to secure by itself a solar panel (1; 10aa; 10ab) to a single beam (4; 4a-4d; 40) of a support structure, comprising an interface (2; 20aa; 20ab) including first fastening means (3; 3a-3d; 30a, 30b; 300a-300d) for securing the solar panel (1; 10aa; 10ab) to the interface (2; 20aa; 20ab) and second fastening means (6, 60) for securing the interface (2; 20aa; 20ab) to the beam (4; 4a-4d; 40), wherein
the first fastening means (3; 3a-3d; 30a, 30b; 300a, 300b) are shaped to retain the solar panel (1; 10aa; 10ab) by affixing the passive face (1b) thereof to a surface (2a) of the interface (2; 20aa; 20ab) or using hooks (3; 3a-3d; 30a, 30b; 300a, 300b) which cover part of the edge of an active face (1a) of the solar panel (1; 10aa; 10ab), and
that the interface includes an intermediate structure (7; 70) which mechanically secures the first fastening means (3; 3a-3d; 30a, 30b; 300a, 300b) and the second fastening means (6; 60) and which fulfills a mechanical dissociation function of the panel (1; 10aa; 10ab) with regard to the beam (4; 4a-4d; 40).

14. The device according to claim 13, wherein the first fastening means (3) are adhesive means or elastic snapping means.

15. The device according to claim 13, wherein the first fastening means (3; 3a-3d; 30a-30d; 300a-300d) are shaped to retain the solar panel (1; 10aa; 10ab) in four peripheral areas.

16. The device according to claim 13, wherein the second fastening means (6; 60) are adhesive means, elastic snapping means, sliding engagement means, or any other means not requiring tools and allowing locking.

17. The device according to claim 13, wherein it includes a plastic body.

18. The device according to claim 13, wherein the intermediate structure (7; 70) includes integrated orientation means (8; 80) to orient the solar panel (1; 10aa; 10ab) along at least one orientation axis (100, 110).

19. The device according to claim 18, wherein the orientation means (8; 80) make it possible to orient the solar panel (1; 10aa; 10ab) along two orientation axes, i.e. an azimuth axis (100) and a declination axis (110).

20. The device according to claim 18, wherein the interface (2; 20aa; 20ab) includes an actuator (9; 90) driven by a control member and capable of actuating the orientation means (8; 80) along the orientation axis or axes (100, 110).

21. The device according to claim 13, wherein the interface (2; 20aa; 20ab) includes integrated electrical connection means (200), capable of transmitting the electricity generated by the solar panel (1; 10aa; 10ab) to the support structure and/or capable of transmitting measurement signals and/or control signals.

22. The device according to claim 13, wherein the interface (2; 20aa; 20ab) includes passages for a coolant between the solar panel (1; 10aa; 10ab) and the support structure.

23. The device according to claim 13, wherein holes or notches are formed in the solar panel (1) and cooperate with the hooks (3; 3a-3d; 30a, 30b; 300a, 300b).

24. An electricity production unit, in particular of the “solar farm” type, including solar panels (1; 10aa; 10ab) each secured to a single beam (4; 4a-4d; 40) of a support structure using a device according to claim 13.
